(19) United States
(12) Patent Application Publication
(10) Pub. No.: US 2016/0322914 A1
(43) Pub. Date: Nov. 3, 2016

(54) INDUSTRIAL PLUG WITH EXTRACTION OF MAGNETIC ENERGY THEREIN

(71) Applicants: Borja RODRIGUEZ RIOS, Santiago (CL); BEUCHAT, BARROS & PFENNIGER, Santiago (CL)

(72) Inventor: Borja RODRIGUEZ RIOS, Santiago (CL)

(73) Assignee: BEUCHAT, BARROS & PFENNIGER, Santiago (CL)

(21) Appl. No.: 15/107,786

(22) PCT Filed: Dec. 24, 2013
(86) PCT No.: PCT/CL2013/000095

§ 371 Date: Jun. 23, 2016

(51) Int. Cl. H02M 7/06; H02J 7/02; H01R 13/717; H02G 1/00; H01R 13/66; H01F 27/28; G01R 31/08

(52) U.S. Cl. CPC H02M 7/06; H01F 27/2823; H02J 7/025; G01R 31/08; H02G 1/00; H01R 13/6691; H01R 13/7175; H01R 13/6683

(57) ABSTRACT

The invention relates to an industrial plug with energy extraction, comprising a power cable and an energy extraction device (506, 507, 801, 802, 1001) such as that presented in FIG. 10/11. This plug has a wide range of uses covering the fields of georeferencing, localisation, lighting, identification, monitoring of variables, inter alia voltage presence, sound generation, capture of electromagnetic fields and energy accumulation in power cables.

### DESCRIPTIVE REPORT

Introduction to the Scope of Application of the Present Invention

At the present time, certain industries have been benefited because of a strong and steady rise in prices of products sold as a result of their activity. This is the case of the Mining Industry worldwide, which for some time has experienced an increase in the international price of the minerals extracted. As a consequence of this phenomenon the operation has been lately focused on increasing production to take advantage of good prices for these products. Such is the case of the mining activity of several minerals such as iron, copper, aluminum, silver, gold, etc.

In order to increase production and take advantage of the mineral's high prices, a good management of certain critical equipment is of the utmost importance. This is common to every industry with intensive use of machinery and in the case of the Mining Industry, an important part of the operational efficiency can be achieved in the first part of the process called “Extraction Process”. This operation includes among other stages: (i) “drilling” in which certain specialized machinery drill the rock; (ii) “explosion” in which each borehole is loaded with explosives. Once detonated, the rock is reduced to sizes suitable to be processed in further steps of the extraction process; (iii) and the last step is “haulage” in which the cracked rock is mounted on large-sized trucks through the loading shovel (111).

In a mining operation there is usually one haulage shovel (111) for every 5 to 10 large-sized trucks (112), so the failure of one of these loading shovels (111) may result in less production and become a bottleneck for the whole mining operation. Therefore, one of the critical equipment in mining operations is the loading shovel (111). In addition to this equipment there are other critical ones such as drilling machines and borers.

Identical operations are performed in underground mining but the equipment models are different especially due to the smaller space available.

Therefore, any improvement made to operate more efficiently this type of equipment, will become into a more efficient mining operation as a whole.

Certain realities will henceforth be exposed about extraction mining operations and how the proposed invention and its applications may help to operate critical equipment more efficiently. One of the events where the present invention will help to have a more efficient operation is in the case of an electrical failure of the cable that powers the critical equipment (shovels (111) and drilling machine), since the recovery time after an electrical failure will be reduced and consequently the availability of the equipment is increased.

This type of equipment such as the loading shovel (111) and some drilling machines are electrically powered. This is due to four fundamental reasons: (i) despite they are mobile equipment, they are not displacing constantly, so they are feasible to be powered by a trailing power cable; (ii) having electrical power input, this equipment presents a lower failure rate than a mechanical equipment with internal combustion engines; (iii) being electrical equipment they are more efficient and (iv) its maintenance is less expensive.

Therefore, the electrical energy supply that powers these critical equipment (shovels (111) and drilling machines) becomes also a critical supply in the mining site. Power is supplied through insulated, flexible, three-phase and medium-voltage cables (8,000 volts) (106, 200) arranged over the same site where the large-sized equipment (drilling machine, shovels (111) and trucks (112)) circulate freely and constantly.

The power cables (106, 200) supplying electricity to critical equipment (shovels (111) and drilling machine) are only 300 meters long. However, the distance from the last mobile substation (109) (power transformer), to the equipment to be powered (loading shovel (111) or drilling machine), is longer than 300 meters.

Considering the above, it is necessary to join cable sections (106, 200) by means of industrial plugs or couplers (107, 108, 500). In this way, from the mobile substation (109) to the equipment (for example the loading shovel (111)), a series of extension cords are used. These extension cords comprise: (i) electrical power cables (106, 200) of 300 meters long and (ii) industrial plugs (107, 108, 500) on both ends of each 300 meters long power cable.

In a mining operation it is not uncommon to have up to 7 extension cords of 300 meters long which means that it is possible to have more than 2,000 meters of medium-voltage cables (106, 200) and 14 plugs (107, 108, 500) all of them laid on the ground, per each of the critical equipment running simultaneously.

As can be understood, the transportation of one of these equipment (loading shovel (111)), in order to continue extracting the mineral in another pit zone, is a highly complex operation. This is because, in addition of moving the loading shovel (111), have to be moved at the same time all the electrical power supply equipment: the 2,000 meters' extension cords (mining cable (106) and plugs (107, 108, 500)) and eventually the mobile substation (109). This operation implies several connections and disconnections of the plugs (107, 108, 500) which operate at 8,000 volts.

Besides, the traffic of these large-sized equipment (loading shovels (111), large-sized trucks (112) and drilling machine) over the same field where the medium-voltage cables are displayed (106, 200), it is risky for the power supply and the safety of the workers operating the equipment if eventually they damage the cables by destruction or severe abrasion when circulating over them.

In addition to this complex situation, the mining operation is usually performed 24 hours a day, so that there are periods of total darkness. Under this condition, cables (106, 200) are more likely to be damaged since their location becomes difficult. Consequently, equipment availability (loading shovel (111)) decreases which might cause productivity reduction in the mining operation.

When an electrical failure occurs in a power cable (106, 200) a section of 300 meters of the cable is damaged. At the mine site this is considered a highly severe event, because one of the critical equipment (loading shovel (111)) has ceased to operate. If there is not a prompt and effective solution to the problem (also focusing operators' health and safety) it may result in a bottleneck for the whole mining operation. In Chile 100 failures take place every month in trailing cables that power critical equipment (loading shovel (111) and drilling machine). These failures interrupt the operation, a situation that takes 1 to 3 hours to be normalized.

When a failure occurs, a protocol is performed whose purpose is to ensure that the critical equipment (drilling machine, loading shovel (111)) will be working as soon as possible and consequently its availability is not diminished too badly. To carry out this protocol in a timely and effective manner, special attention should be paid to the operators' safety who will be cooperating to overcome the emergency.

The protocol basically consists in: (i) detecting the faulty section of the cable (106, 200) of 300 meters; (ii) removing the faulty cable section by disconnecting the power plugs (107,108, 500) in both ends of the power cable; and (iii) replacing the faulty section with a new section of 300 meters in good conditions.

This protocol seems very simple, but it has some complexities when the reference scenario where it will be carried out is taken into account: long distances due to large extensions of land, sometimes in darkness, low temperatures, geographic altitude, cable weight (1.5 to 3 tons per section of 300 meters), plug connections (107, 108, 500), high voltage and high currents involved, etc.

As described in previous paragraphs, the first step of the protocol is to detect the faulty cable section (106, 200). In addition to the supposed electric problem causing the failure, another problem to be solved is to locate the cable on the field. That is to say, if it is not possible to physically see the cable (106, 200), much more difficult will be to come up with a conclusion of the electrical state of the cable.

However, the loading shovel (111) that stops working because of an electric failure is always easy to be located. Thus, from the loading shovel position, the cable (106, 200) is checked until the failure is found out. But this process is very slow because, as mentioned before, the cable length can be about 2,000 meters.

At this protocol stage it would be extremely useful to have a field tracking device for locating the plugs (107,108,500) that are on the ends of each power cable section (106, 200) resulting in a more expeditious operation. The assisted location of the plugs (107,108, 500) can be carried out by means of the emission of signals from each industrial plug: geographical positioning (GPS signal), radiofrequency signal emissions, light emission, etc. This means that each of the plugs (107, 108, 500) installed on the field must develop a new functionality in addition to its primary one: to electrically connect sections of power cable in order to ensure the transmission of electrical power to the critical equipment (drilling machine, loading shovel (111)).

The second step of the described above protocol consists in unplugging (107, 108, 500) both ends of the faulty cable section (106, 200). However, this is not as simple as unplugging low-voltage electrical equipment. The disconnection of cables supplying power to medium-voltage equipment (8,000 volts in this case) involves high risks for the people carrying out the operation. These risks may have fatal consequences if the person does not have the expertise or knowledge to carry out this work. It is very important to determine if the cables are de-energized when they are going to be unplugged.

The plug (107, 108, 500) is safe from outside only if it is connected to another plug (107, 108, 500). Thus, if medium voltage is present during unplugging, an electrical arc will be generated between phases which might hurt or injure the operator that is performing this operation

Under these conditions, the feasibility of implementing these plugs (107, 108, 500) with a device that alert the operator about the presence of dangerous voltage, especially during disconnection process, is certainly a valuable contribution for the persons' security and the productivity of this industrial activity. This means that each and every plug (107, 108, 500) must have this new function which is to detect voltage presence. This function is additional to its primary function which is to connect electrically cable sections of 300 meters to assure the electrical power supply for the critical equipment.

A second event where the present invention will help to have a more efficient operation is during the process of transportation of the critical equipment (loading shovels (111)). This is because mining exploitation is planned by zones, that is to say, a given sector of the mine is worked (drilling, explosion, haulage) and these operations are repeated over and over in different pit areas, most of the time simultaneously. These zones are not necessarily located close to each other. This implies that it is necessary to move the huge mobile equipment (loading shovels (111)). As this equipment is electrically powered, the transportation of it involves a series of connections and disconnections which have the same risks previously described. So, in order to safely move the loading shovel (111), would be very useful to have information about voltage presence in the electrical supply lines.

All these new functionalities (to detect voltage presence, emit a variety of signals, indicating its position and state) can exist separately or co-exist in an industrial-style plug (107, 108, 500), but they require to be connected to an electrical source to be powered and thus to be at the service of people and industry.

This invention consists on an industrial plug (107, 108, 500) which is equipped inside with an electrical energy harvesting device (506, 507, 801, 802) and diverse appliances (represented generically by a load (803)) that give new functionalities to the industrial plug (107, 108, 500) for a greater productivity and industrial security.

From now on, mining will be used only as an example of a particular industry, but it does not mean that the present invention application is restricted only to this activity or to any of the forms of exploitation through open pit mining method and/or underground mining operation, no matter the size: large, small and/or medium-scale mining or a particular equipment with the exception of those powered with low, medium and/or high voltage.

Description of the Previous State of Art

This invention consists of an industrial plug (107, 108, 500) with various functionalities that are possible thanks to its design that includes an electrical energy harvesting device and diverse appliances (generically represented by a charge (803)).

At present, exist an industrial plug (107, 108, 500) with only one functionality in addition to the plug's primary functionality (to connect electrically two power cable ends (107, 108, 500)).

That industrial plug (107, 108, 500) gives information of voltage presence when the operator is disconnecting the plugs (107, 108, 500). This support given to the operator is performed by means of warning lights indicating voltage presence in each phase. This warning light can be seen from outside the plug (107, 108, 500).

However, this plug, currently in the market, has only that single functionality (emission of a warning light when voltage is present) and the signal emitted is very weak to be detected effectively in an open pit mining. Additionally, the plug cannot perform other functionalities because the amount of energy extracted is very small (it is just a signal with power magnitude in the order of miliwatts) and only is enough to feed small lights indicating the presence of voltage.

The plug trademark is Ausproof®, with its model 11kV and 800 A of manganese bronze alloy that complies with the explosion-proof standard AS1300 and holds the patent AU1981004 “Cable earth fault indicator”.

Another plug for detecting voltage with registered trade mark “Seamless Mining Products” (SMP) with its model 11 kV Ex-d Bolter Coupler which besides being IP68, complies the standards IEC ex-IEC 60079, IEC 60060093, IEC 50112, IEC 50243, AS/NZS 60079, AS/NZS 1300, ISO 9001, ISO/IEC 80079-34.

The present invention is an industrial plug (107, 108, 500) whose design contains a device (506, 507, 801, 802) to harvest electrical energy inside, and diverse appliances (generically represented by a charge (803)) which gives the plug (107, 108, 500) functionalities to achieve a greater productivity and security in the industrial activity.

The device (506, 507, 801, 802) to harvest electrical energy inside the industrial plug (107, 108, 500) has at least: (i) a power cable, normally three-phase (106, 200) represented in FIG. 2/11; (ii) at least one of the phases of the power cable (201, 505, FIG. 8/11); (iii) a device to harvest electrical energy (506, 507, 801, 802) and (iv) a load (803) which is the generic and schematic representation of the diverse appliances that give new functionalities to the industrial plug (107, 108, 500).

Additionally, as the diverse appliances (represented by a generic charge (803)) use direct or continuous current to operate, the system can have additionally: (v) rectifier diodes; (vi) condensers for smoothing electrical waves and (vii) voltage limiters.

So far, the device (506, 507, 801, 802) only delivers energy to the load (803) (diverse appliances) if there is a current circulating through the power cable. So, if energy is required even if there is no current circulating through the power cable (viii) batteries capacitors, super capacitors can be incorporated to the system.

In the following paragraphs, the importance of having a support system for plugs disconnections and the solutions existing at the present moment will be detailed.

In open pit mining, the electrical distribution system inside the open pit (FIGS. 1/11 and 3/11) is based on a trailing power cable (106, FIG. 2/11, 303) which operates on the field surface with medium-voltage (8,000 volts). Because of the fact that the trailing cable operates over the field, for security reasons, it is an insulated power cable (106, 200) and provides ground connection (208 and 305) to the all the equipment that is part of the electrical distribution system: plugs (107, 108, 500), loading shovels (111, 302), drilling machines (302), substations (109, 301), etc.

Additionally, of providing ground connection, the trailing power cable should provide safety when connecting and disconnecting plugs (107, 108, 500). This safety is provided by the trailing power cable thanks to the pilot wire (207 and 304) that is placed inside the trailing power cable.

FIG. 2/11 shows a medium-voltage three-phase cable and its complexity. It has several elements and each of them has several layers.

This kind of three-phase power cable is the one used in the Large Mining Industry to supply electricity to different types of equipment and especially to the shovels (111) that load the large-sized mining trucks (112).

FIG. 2/11 shows the cable employed in detail. It is a medium-voltage three-phase cable (201A, 201B and 201C) each comprising a main conductor (202), a primary internal semi-conductive layer (203), its electrical insulation (204) an external semi-conductive layer (205) and an electrostatic screen (206). Additionally, the cable has a fine pilot wire (207 and 304) and two ground cables (208), all covered with an outer jacket (209).

The fine pilot wire (207 and 304) is a control wire inside and along the power cable, which transmits signals related to the state of the power cable.

As mentioned above, the pilot wire (207 and 304) plays a key function inside the trailing power cable which is the transmission of electrical signals related to the operation of the trailing power cable and the electrical distribution system that goes from the electric substation (109 and 301) to the energized equipment (111) just as it may be observed in FIG. 3/11.

FIGS. 3/11 and FIG. 1/11 show a scheme of the electrical energy transmission and distribution system. The energy is transmitted from the substation (109 and 301) to the mobile equipment (111 and 302).

The flexible trailing cable (106 and 303) is schematized as the set of the three phases (306A, 306B, 306C), the grounds (305) and the pilot wire (207 and 304). The pilot wire (207 and 304) and the grounds (305) deliver a signal to the main relay (302) located in the substation, which, in turn, triggers the circuit breaker or isolation switch (307), also located in the substation.

When a pair of plugs is disconnected (107, 108, 500) the pilot wire is the first element of the trailing power cable to be mechanically disconnected. When this happens, the continuity of electricity in the pilot wire is lost. When the loss of continuity in the pilot wire (207 and 304) is captured by the relay (302), this one commands the isolation switch (307) in the substation (109, 301) in order cut-off the power supply (voltage and current) in the entire circuit. This is the only protection that the system gives to the operator before the disconnection process. It should be noted that if the protection fails while disconnecting plugs (107, 108, 500), voltage will be present in the electric line and this operation becomes highly dangerous.

The relay (302) also monitors the electric continuity of the grounds (305) so to assure the whole system be grounded. If the electric continuity loss in grounds (305) is captured by the relay (302), this one also commands the isolation switch (307) to cut off the power supply (voltage and current).

It should also be noted that as both signals (pilot wire continuity (207 and 304) and grounds continuity (305)) must be monitored separately, the relay (302) also monitors the short circuit between the pilot wire (207 and 304) and the grounds (305) so as to guarantee the monitoring and control of both continuities separately.

On the other side, the trailing power cable (106, 200) used in the Large Mining to supply power to the drilling machines and loading shovels (111), is a flexible cable (FIG. 2/11). During operation, it is impressive to observe the flexibility of this large diameter trailing power cable (an outer diameter of 70-80 mm.). This flexibility is achieved because of three features of its constituent elements: (i) the copper conductors (202) and the grounds (208) are made of a number of very thin filaments or strands; (ii) the main conductor's insulation (204) is very thin and flexible; (iii) the cable jacket (209) is made of a very flexible material (Hypalon® or Polyurethane (TPU)).

However, in most of the standard models of flexible trailing power cables for mining, the pilot wire (207 and 304) is not designed to be as flexible as the rest of the cable components. In fact, the pilot wire is made out of wires with a larger diameter than the wires of the conductor and its insulation is not quite flexible. So the intensive use of the trailing cable, the minimum bending radius (for example when there are knots on the trailing power cable) and the difference between the flexibilities of the cable itself and the pilot wire (207 and 304) may cause a failure in the pilot wire. This makes it to loose electrical contact and send out a signal to the safety system and consequently the electricity supply for the critical equipment is cut off. This is known as a false alarm, since the pilot wire (207 and 304) when loses continuity sends a signal meaning the system is about to be open (just as if two plugs were being unplugged (107, 108, 500)). In this moment, the relay disconnects the whole system and therefore the loading shovel (111 and 302) runs out of power. If this situation occurs constantly, a number of operational problems arises because the loading shovel (111 and 302) stops operating because of a faulty material and not by security reasons in the installation.

It is important to note that if a line has 7 sections of 300 meters of cable, they all have to be in perfect conditions so to assure the good performance of the system without generating false alarms. This is often difficult to be achieved because there are generally new and used cables together in a same line.

The problems arising from these conditions make the operation impracticable. In fact, there are mining operations that work with the pilot wire (207 and 304) disconnected to avoid operational problems (false safety alarms), but they face serious problems in safety and concern of the people. Other mining companies operate some of their distribution lines from the mobile substations (109) to the mobile equipment (111 and 302) without the pilot wire (207 and 304) connected to the safety system, thereby infringing operational safety and concern for the people. There are other mining companies that use cables with a special design. Such is the case of the Peruvian mining company Antamina. The design employed is a pilot wire (207 and 304) with thin copper filaments that give more flexibility to the wire. Each of these filaments has a tin coating for reducing friction in the threads. This way, a better performance and flexibility are achieved and consequently a longer service life for the pilot wire (207 and 304).

In short, the pilot wire (207 and 304) is designed to protect the operator when plugs (107, 108, 500) are being disconnected. When unplugging the first element mechanically disconnected is the pilot wire (207 and 304) and consequently the entire system will be without electric power and voltage. A problem arises when the pilot wire produces a false alarm which makes the system be de-energized constantly. This situation prevents from performing a faultless mining operation and some mining companies let the system operate without pilot wire, consequently without protection for the operators who have to disconnect the plugs.

When decisions have been made about operating without pilot wire in order to avoid false alarms, operators work under a constant risk and therefore an extremely efficient coordination should exist between the operator who disconnects the plugs (107, 108, 500) and the operator who activates the circuit breaker at the substation and thus preventing the first one from suffering an electric shock when disconnecting the plug (107, 108, 500). The previously described protection system becomes more necessary in underground coal mining where the presence of firedamp (methane basically) may form an explosive atmosphere.

The plug which is part of the previous state of the art, is especially designed for working in this underground environment. For example, its whole surface is made of bronze, because this metal does not produce sparks when crashing violently against another surface.

As the plug (107, 108, 500) is not designed to be disconnected with current or voltage presence, when a disconnection occurs under this conditions, a resulting phase to phase and/or phase-ground electric arc is expected.

In this kind of environment (in underground coal mining) even the smallest electric arc may generate a major explosion.

If that environment is considered to be an explosive one, special precautions should be taken when disconnection is taking place. Every precautionary measure in security is welcome. That is why in these underground coal mining, voltage indicators in each of the phases are used in addition to the pilot wires (207 and 304). In this way, the operator can get additional information about the plug state (107, 108, 500) to be disconnected and he will do it only when the absence of the warning light indicates the absence of voltage.

In the market there are trademarks of mining plugs (107, 108, 500) especially used in underground coal mining which are equipped with light warning indicators of phase voltage.

An example is Ausproof® in its model 11kV and 800A of bronze manganese that complies with the explosion-proof standard AS-1300 and is patented AU19810041318 “Cable earth fault indicator.

Another sample of trademark is “Seamless Mining Products” (SMP) with its model 11kV Ex-d Bolted Coupler which besides being IP68 , meets the standards IEC 60079, IEC 60093, IEC 50112, IEC 50243, AS/NZS 60079, AS/NZS 1300, ISO 9001, ISO/IEC 80079-34

Both solutions have the voltage presence warning light by capturing the radial electric field with a conducting element (copper or aluminum sheet) after the primary insulation (204) and before the external semi-conductive layer (205) in each of the phases of the cable that are available inside the plug. By doing this, the conductive element has a high voltage in relation to the ground installation of the system. The light emitting element is subject to that voltage by connecting it between the sheet capturing the electric field and the ground (earth) or between two sheets of different phases. This configuration allows to capture a very limited quantity of energy on the order of miliwatts or dozens of miliwatts.

As previously mentioned, these commercial solutions are used in underground coal mining where there is no light, therefore with the scarce available energy (of the order of miliwatts or dozens of miliwatts) it is possible to have a relatively significant light signal. However, this solution cannot be applied in open pit mining since the low intensity signal may be not seen clearly by the user.

Furthermore, this commercial product has only the additional function of detecting voltage since the low amount of energy provided does not allow to power other devices (generically represented by a charge (803)) such as GPS (its energy consumption is at least 10 watts), LED lights to illuminate the plug (their power consumption is at least 5 watts) etc.

Solution Requirements

The solution refers to the development of an industrial plug (107, 108, 500) with an electric energy harvesting device inside (506, 507, 801, 802). It draws energy from the main conductors of the power cable, inside the industrial plug (107, 108, 500) without making electrical contact with them, but harvesting the electromagnetic energy present in each of the phases of the three-pole cable.

This energy is used to electrically feed several devices which are also inside the industrial plug (107, 108, 500). These devices perform a series of functions and emit signals by several means through the plug (107, 108, 500). Functions performed by several devices are described below.

The requirements listed below are related to the industrial plug (107, 108, 500) with an electric energy harvesting device and several appliances inside which make the industrial plug (107, 108, 500) perform diverse functionalities:
1. It should comply with the primary functionality of an industrial plug which is the ability to transmit electricity safely among the sequential extension cords. That is to say designed to handle high voltages and currents for a safe operation for people.
2. The harvesting energy device (506, 507, 801, 802) inside the industrial plug (107, 108, 500) should be able to harvest enough energy to power diverse appliances. It should be able to harvest at least 5 watts.
3. The diverse appliances (generically represented by a load (803)) powered by the energy harvesting device (506, 507,801,802) which is inside the industrial plug (107,108, 500) should be able to communicate with the outside surrounding of the plug (107, 108, 500) through different means by emitting telecommunication signals (radiofrequency, GPS) light signals and/or sound allowing the user to identify the plug state and/or location (107, 108, 500).
4. The telecommunication signals emitted should be always available even if the mobile equipment is not working (not consuming electric current). This requires backup elements (batteries) inside the plug (107, 108, 500), which need to be charged and recharged when the mobile equipment is operating (flowing current through the main conductors of the trailing power cable).

This requires the energy extracted from the cable should be equal to or greater than the energy consumed.

For all the reasons given and taking care not to damage the batteries, the device should be able to limit the battery charge and indicate when it is fully charged.

5. The telecommunication light and/or sound signals should be detectable by any user through any means under the most real and varied environmental conditions of light, temperature, noise, pollution, etc. and taking into consideration the operation type, the field dimensions and the machinery.
6. The signal emitted by the device (generically represented by a charge (803)) should have the least amount of limitations regarding the signal reception. In the case of a light signal, limitation refers to the observer's angle of vision and the light signal intensity.
7. It should not require an additional energy source (506, 507, 801, 802) to the one already present in the surroundings of the cable (electromagnetic energy).
8. The energy harvesting device (506, 507,801, 802) located inside the industrial plug (107, 108, 500) should be a reliable energy source. This is achieved when said energy comes from the electromagnetic energy around the same cable.
9. This solution uses the electromagnetic field formed by currents flowing through the main conductors of the trailing power cable. Undoubtedly this is an energy source present in each phase of the power supply cable.
10. The energy harvesting device inside the industrial plug (107, 108, 500) should not be electrically connected to the phase conductors because the high voltage they have (8,000 volts) would require insulators or transformers with unacceptable dimensions for the operation.
11. The energy harvesting device (506, 507, 801, 802) and the diverse appliances inside the industrial plug (107, 108, 500) should not imply an increase in the plug dimensions (107, 108, 500).
12. The energy harvesting device (506, 507, 801, 802) inside the industrial plug (107, 108, 500) should not imply a considerable change on how to install the same plug (107, 108, 500) in the electric distribution line.
13. The new industrial plug (107, 108, 500) with all its devices inside should not have an excessive weight when compared to the current industrial plug in use.

The present development is an industrial plug (107, 108, 500) from which interior enough electromagnetic energy is drawn from the three-phase cable itself (of the order of units or dozens of watts), allowing to supply power to diverse appliances (generically represented by a charge (803)), which indicates the state of the plug (107, 108, 500) in the field (temperature, humidity) and the state of the transmission and distribution of electric power (current, voltage).

The appliances (generically represented through a load (803)) can be diverse (light-emitting diodes, sound and/or telecommunication signals (radiofrequency, GPS, etc.) and are able to deliver signals to remote mechanical elements without restricting the extraction and application of energy to these devices.

This invention solves the problems of the prior art mainly concerning the amount of energy extracted from the cables (units or dozens of watts) and is a real solution for the industry since it meets the requirements for detecting the presence and state of plugs (107, 108, 500), and the state of the transmission and distribution of electrical power for the critical equipment.

At the same time, it should be noted that this invention does not increase significantly the plug weight which is at most 10% higher in weight and dimensions of the traditional plug. Besides, there are no modifications to the plugs installation and conventional connection.

The Scope of Application of the Present Invention

In addition to the previously described industries (mining), the present invention solves problems of various other industries. From now on some of these application industries will be appointed without restringing the scope of the present invention to potential fields of application.

The application fields have been classified into the following categories:
1. Location of industrial plugs (107, 108, 500): the new industrial plug that has inside an electric energy harvesting device (506, 507, 801, 802), allows to power a load or appliance which, in turn, allows the industrial plug (107, 108, 500) to be located by means of luminous, sound or telecommunication signals (radiofrequency, GPS, etc.)
2. Monitoring of variables and/or parameters by industrial plugs (107, 108, 500): the new industrial plug that has inside an electric energy harvesting device (506, 507, 801, 802), allows to power a load or sensor which, in turn, could be able to: (i) monitor operation variables (voltage, current, temperature, humidity, pressure, etc.), (ii) and eventually store and (iii) transmit them as information.
3. Use of batteries inside industrial plugs (107, 108, 500): the new industrial plug that has inside an electric energy harvesting device (506, 507, 801, 802), allows to store the collected electrical energy in batteries, capacitors, super capacitors, etc. Thus, the stored energy is used to maintain supply of the mentioned loads even if no current is flowing through the main conductor of the trailing power cable. The service life of the loads supplied from the batteries will depend on the loads consumption, the battery capacity and the range of charge and discharge times of them.

Technical Problems Solved by the Invention

As previously described herein, the solutions existing in the market, whose indicators consider the presence of voltage in each phase, are used in underground coal mining, where the protection system by means of the pilot wire (207 and 304) is used redundantly. In this way, the operator can obtain additional information about the industrial plug state (107, 108, 500) he is about to disconnect. However, he will do it only when the voltage warning light indication be off. When this happens, the pilot wire (207 and 304) should operate.

The system currently existing in the market captures minor differences of electrical potential from the electric field among the cable phases. This causes a minimum electric current to power the light emitting source. This low electric energy to emit a signal (of the order of miliwatts or dozens of miliwatts) prevents some required appliances (georeferenciation, illumination of plugs, etc.) from functioning.

On the basis of the above mentioned, the system currently existing in the market has an adequate performance in low-light environmental conditions. However, the ambient lighting conditions in open pit mining are quite different.

In open pit mining the poor signal strength presented by the currently existing system, does not assure the signal is clearly perceived by the user, even at night.

The system proposed herein ensures a higher intensity signal with a power output of more than 1000 times in comparison with the currently existing solutions in the market.

Description of the Invention Itself

It should be understood that the present invention is not limited to a particular methodology to be followed, composite materials, manufacturing techniques, uses and applications described herein, since they can vary. It should also be understood that the terminology employed herein is used to describe a specific representation and is not intended to limit the perspective and potential of the present invention.

We shall define power cable as a conductor (generally made of copper) or a set of electrical conductors covered with insulating or protective material.

We shall define a three-phase power cable as three power cables representing each phase covered with insulating or protective coatings or materials.

It should be noted that the use of singular form herein concerning the product specifications and throughout the entire text does not exclude the plural, unless the context otherwise requires.

For example, reference to “one” element is a reference to one or more elements and includes equivalent forms known by those who are knowledgeable in the subject (the art).

Similarly, the reference to “a step”, “a stage” or “a way or mode”, is a reference to one or more steps, stages or modes and may include implicit and/or supervening steps, stages or modes.

All the conjunctions used should be understood in their widest sense possible. For example, the conjunction “or” should be understood in its logical orthodox sense and not as an excluding “or” unless the context or the text specifically requests otherwise. Structures, materials and/described or elements described also refer to those functionally equivalent. This way limitative and exhaustive lists are avoided.

The expressions used to indicate approaches or conceptualizations should be understood in their explicit meaning unless the context gives a different meaning.

Technical names and/or scientific terms used herein have the common meaning given by a person qualified in this matter unless expressly stated otherwise.

The methods, techniques, elements, equipment and materials are described herein, even if similar and/or equivalent methods, techniques, elements and materials can be used or preferred in the practice and/or testing of the present invention. It should also be understood that the description made of the structures herein refers to any similar structure or functionally equivalent.

All patents and other publications are included as a reference with the purpose of describing and/or informing, for instance, the methodology described in such publications that might be useful regarding the present invention. These publications are included only as a source of the existing information before the register date of the present patent application.

In this regards, nothing should be interpreted as an admission or acceptance, rejection or exclusion with respect to the authors and/or inventors are not entitled or that such publications are dated before other previous ones, or by any other reason,

The scope of the present invention is an industrial plug (107, 108, 500) inside which there is a device that extracts or harvest electric energy (506, 507, 801, 802) from bare power cables or from power cables with their protector and/or insulation, of one or more phases, of low, medium or high voltage.

The scope of the present invention is an industrial plug (107, 108, 500) holding an energy extraction device (506, 507, 801, 802) which also allows accumulation of the extracted energy by means of batteries, capacitors, super-capacitors, etc.

The scope of the present invention is an industrial plug (107, 108, 500) that allows geo-referenciated information (sensor) to capture the geographic position of the industrial plug (107, 108, 500) and is electrically powered by the energy extraction device (506, 507, 801, 802) and/or by storage and backup batteries.

The scope of the present invention is an industrial plug (107, 108, 500) that allows a sensor to capture the magnitude of a particular variable (temperature, current, voltage, humidity, etc.) and to emit a signal with information to the user about the relevant parameters. It is electrically powered by the energy extraction device (506, 507, 801, 802) and/or the storage and backup batteries.

The scope of the present invention is an industrial plug (107, 108, 500) that allows its own illumination. This illumination is achieved by means of the electrical supply from the energy extraction device (506, 507, 801, 802) and/or energy stored in backup batteries.

Description of the Industrial Plug Inside which the Energy Extraction Device is Located

The industrial plug (107, 108, 500) is basically a set of pieces attached to a hollowed, grounded, central housing with reinforcement ribs in the inside that give to it the necessary mechanical strength to withstand mining operation. It is preferably made of aluminum, but it might also be made of bronze or even a polymer material.

The plug mainly aims to join cables. So, it should ensure the electric current flow from one cable to another and control the electric field produced by the 8,000 volts. In order to do so, it has a series of insulators inside.

The plug has two ends: (i) the three-pole cable (501) is plugged in one of the ends and by tightening the cable outer jacket (209) with the gland or stuffing-box (402) the cable is fixed to the plug safely. The other end of the plug is the face where to connect another plug.

At the connection end, the three phases are independent (out of the jacket). When two plugs are connected, the three phases make the electrical connection through the connector pins (503).

The plug is internally arranged in such a way that enough space is generated for the energy harvesting device (506) to be integrated (incorporated) inside the central housing or the stuffing-box as seen in FIG. 5/11. That is to say, the electrical energy harvesting device (506) is located inside the plug in the nearest section to the terminal union where the phases are out of the jacket of the cable and separated from each other.

This configuration and arrangement is the same for male and female plugs and for those plugs do not require gender characteristics to operate.

Description of the Electrical Energy Extractor Device (506, 507, 801, 802)

This energy extractor device (506, 507, 801, 802) has the following elements: (i) energy harvester (801, 802, 9001, 1001), (ii) voltage rectifier/regulator (1101), (iii) backup battery (1002), (iv) information-process card, (v) detector/sensor (1104) and (vi) signal transmitter (1105) all included inside the plug (107, 108, 500).

As can be seen in FIG. 10/11 the plug operation is as follows: (i) the energy harvester (801, 802, 901, 1001) captures the electromagnetic field produced by the high circulating currents (of the order of dozens and hundreds of Amperes) in each one of the phases already separated inside the plug (107, 108, 500); (ii) the alternating current electric power is rectified (transformed into direct current) by the rectifier (1101), (iii) to feed an electric battery (1002) acting as a regulator and accumulator of energy at a time. (iv) This battery (1002) supplies, in turn, electric power to any of the devices (1104) capturing and/or emitting (1105) certain warning signals with information to the user.

The backup batteries (1002) continuously supply the harvested energy with magnitudes of dozens of watts enough to emit warning light, telecommunication (radiofrequency, GPS, etc.) and/or sound signals, completely able to be transmitted and detected by any user.

The energy harvesting device (506, 507, 801, 802) has the following features: (i) it collects (harvests) electric energy (506, 507, 801, 802) from a power source (the main conductors of the power cable itself) for any of the functionalities intended for the industrial plug (107, 108, 500); (ii) it is totally integrated inside the industrial plug (107, 108, 500); (iii) it modifies minimally the industrial plug (107, 108, 500) installation process.

In order to operate correctly, the energy extractor device has two components. They are: (i) one or more phases (main conductors) of an electric power cable to extract energy from the same power cable and (ii) an electric energy extractor device (506, 507, 801, 802)

The electric energy extractor device (506, 507, 801, 802) considers the use of three basic components (1, 2, 3) and one optional (4):
1) Ferrous core (open or closed)
2) Copper coils
3) Electric loads determined by the use of the energy extracted by the system (for instance, the illumination of cable, emission of telecommunication, sound signals, etc.)
4) Storage backup batteries. The energy extracted from the cable can be previously stored by batteries, capacitors and/or super-capacitors before being consumed by the respective loads and different uses.

FIG. 8/11 shows the energy extraction system implemented in one of the phases of the cable.

As previously mentioned, the electric energy extractor device (506, 507, 81, 802) considers the use of three basic components:

1) Core: made of ferrous material, it concentrates in all its volume the perimetral magnetic field present in any conductor through which a current is flowing.

The geometry of this concentrator material of magnetic field can be varied: solid body, plate packs rings, wires, or several wires of smaller diameter.

Concerning the material, it may be any ferromagnetic one, on the understanding that it is a good conductor of magnetic field. It can be any conducting material of a magnetic field such as galvanized iron, cast iron, black wire, steel, some kinds of stainless steel preferable siliceous iron, or related material.

The material of this core is very important, since the magnetic field created only by the electric current present prefers to travel through distance in a ferrous medium than in a medium such as air. The concentration of the magnetic field and the reduction of all the dimensions of the system are, therefore, achieved.

The core of the electric energy harvesting device (506, 507, 801, 802) is preferably a closed core type but if installation is taken into consideration, the core may also be open type with the possibility to be closed.

2) Coils made of wires of any electrically conductive material such as aluminum, silver, gold, etc., and malleable, electrically insulated, preferably enameled annealed copper.

The coils are a length of wire arranged into a series of rings around the core.

A voltage created by the change in the magnetic field concentrated by the core is induced between the terminals of these coils.

The extracted energy allows to electrically supply one or more loads which define the use or application of the system and its different uses.

3) The loads (803) connected to the coils will depend on the application intended to put into operation. Some examples are: LEDs to generate a luminous signal, sound emitters, telecommunication transmitters (GPS, radio stations, etc.) voltage detectors being able to emit signals, elements to monitor parameters, information emitters to give an account of the captured information.

4) Accumulators (backup batteries): The loads (803) can be connected to the coils if they are required to work only when there is current in the main cable or, through an electrical energy storage device such as a capacitor or a battery, if a system requiring prolonged use is needed (even if there is no current flowing in the conductor).

Industrial-Style Plug with Energy Extractor

According to the descriptions, it is concluded that the characteristics of this invention are summarized as follows:

1) It is able to maintain the present size of an industrial plug (107, 108, 500) for trailing power cables.

2) The energy harvester device itself is an energy source which only requires the same current supply of the critical equipment for its efficient operation.

3) Its power supply comes only from the magnetic energy available outside each phase of the power cable, being able to be implemented in one or more phases.

4) It only requires a determined quantity of current be circulating through the implemented phase. As the cable supplies energy to equipment with practically 24 operating hours, the current flows continuously through the cables and therefore a permanent energy source is available for the energy harvesting device.

Under these specific energy supply conditions, the plug proposed and implemented in a power cable is an important contribution to the industry.

The functions of emitters and detectors for each application of the industrial plug with energy extraction system inside it are summarized below.

| Plug | Sensor | | |
|---|---|---|---|
| functionality | description | Emitter description | Observation |
| Voltage detector | Antenna that | LED outside the | This way the user knows the |
| | captures | plug (for instance | state of voltage detector system |
| | electrical field | Red-colour that | and voltage presence |
| | Phase-Earth | informs the user the | |
| | | presence of voltage. | |
| To inform plug | There is no | LED outside the | The user knows plug position |
| presence | sensor | plug (for instance | and so it is easier to locate it |
| | | green colour that | and solve the emergency |
| | | informs the user the | because of the faulty cable and |
| | | state of the backup | where it is necessary to unplug |
| | | battery) | each end of the faulty cable |
| | | | and plug a new section in good |
| | | | conditions. |
| To inform plug | GPS signal | GPS signal emitter | Signal emitted by the plug is |
| position | receiver | | transmitted to a station that |
| (georeference | | | indicates the position of each |
| information) | | | plug in mining operation. |
| To inform on | Sensor of humidity, | Radio Frequency | This way, the user knows first |
| certain | temperature, current, | emitter with | about the parameter in |
| parameters | voltage, etc. | information about | particular. |
| inside the plug | | a parameter in | |
| | | particular. | |

Energy Storage

The scope of the present invention is an industrial plug with an electrical energy harvester device located inside, that also allows the storage of the energy extracted by the use of backup batteries, capacitors, super capacitors, etc. and their different uses.

FIG. 10/11 is a general scheme of the system: main conductor of the three-pole cable (202), harvester (801+802), rectifier (1101), voltage limiter (1102), battery (1103), sensor (1104), emitter (1105).

The rectifier (1101) transforms alternating current into direct current. Typically, it is an arrangement of 4 diodes forming a Weston bridge and a capacitor smoothing the wave to get a pure direct current.

The voltage limiter (1102) aiming at defining the voltage applied to the battery with the purpose of extending its service life.

The battery (1103) acts as an energy backup when there is no current in the three-pole power cable. The battery gives energy to the sensor and the signal emitter

Voltage detection in industrial plugs (107, 108, 500)

The scope of the present invention is related to a voltage detector (sensor) which captures the electric field signal of the three-pole power cables of low, medium and/or high voltage.

The sensor passes a signal which once amplified it is emitted as information to the user about the state (voltage) of the electrical line: with presence or without presence of voltage.

The sensor is powered by the energy harvesting device (506, 507, 81, 802) which extracts energy from the main conductors of the power cable or by energy storage from the backup batteries.

FIG. 10/11 is a general scheme of the system: main conductor of the three-pole cable (202), harvester (80i+802), rectifier (1101), voltage limiter (1102), battery (1103), sensor (1104), emitter (1105).

The signal (1104) that captures a determined signal. In this case, the signal intended to be captured is the voltage in each phase of the cable. This sensor is electrically powered by the battery so that it can be performing its function during the time the battery charge be sufficient to make it work.

The emitter of signals (1105) emits a certain signal to provide useful information to a receiver (1106). In this case, the emitter would inform about the voltage presence in each phase of the cable. This emitter is powered by the battery, so that it can be performing its function as long as the battery charge be sufficient to make it work.

The receiver of the signal (1106) may be a determined element or a person to whom the emitted signal may be relevant.

Geo-References of the Industrial Plugs

The scope of the present invention is related to the geo-references (sensor) which capture the positioning signal (altitude, latitude, longitude) of the industrial plug (107, 108, 500), by giving information about its geographic position to the user.

The sensor is powered by the energy harvesting device (506, 507, 81, 802) which extracts energy from the main conductors of the power cable or by energy storage from the backup batteries.

FIG. 10/11 is a general scheme of the system: phase of the three-pole cable (202), harvester (801+802), rectifier (1101), voltage limiter (1102), battery (1103), sensor (1104), emitter (1105).

The signal sensor (1104) captures a determined signal. In this case, the signal aims at the plug position. This sensor is powered by the battery so that it can be performing its function as long as the battery is sufficiently charged to make it work.

The emitter of signals (1105) emits a certain signal to provide useful information to a receiver (1106). In this case, the emitter informs about the location of the plug through a GPS. This emitter is powered by the battery, so that it can be performing its function as long as the battery charge be sufficient to make it work.

The receiver of the signal (1106) may be a determined element or a person to whom the data emitted by the signal may be relevant.

Monitoring Parameters and Signal Emission

The scope of the present invention is related to a sensor that captures the magnitude of a determined variable (temperature, current, voltage, humidity, etc.) and provides the user a signal with information about the relevant parameters. The sensor is powered by the energy harvesting device (506, 507, 81, 802) which extracts energy from the main conductors of the power cable or by energy storage from the backup batteries.

The signal emitter (1104) captures a determined signal. It may be temperature, current, humidity. This sensor is powered by the battery so that it can be performing its function as long as the battery is sufficiently charged to make it work.

The signal emitter (1105) emits a certain signal providing useful information to a receiver (1106). In this case, it could be the state of the distribution line, or the magnitude of a determined parameter. This emitter is powered by the battery, so that it can be performing its function as long as the battery charge be sufficient to make it work.

The receiver of the signal (1106) may be a determined element or a person to whom the data emitted by the signal may be relevant.

Illumination of the Industrial Plug

The scope of the present invention is related to the illumination of the industrial plug (107, 108, 500). The lights are powered by the energy harvesting device (506, 507, 81, 802) which extracts energy from the main conductors of the power cable or by energy storage from the backup batteries.

The signal emitter (1105) indicate the presence of the industrial plug, so that it can be easily detected. This emitter is powered by the battery so that it may be performing its function as long as the battery is with enough charge to make it work.

The receiver of the signal (1106) is a person to whom the data emitted by the signal may be relevant.

Example of Application of the Energy Extraction System

The practical example of application of the industrial plug with an energy extractor device inside, is the illumination of the plug so that it may be seen from the outside. It can be seen in FIG. 10/11. However, this is only an example with no restrictions about the use of the electric energy harvesting device (506, 507, 801, 802) for other applications.

The illumination of the industrial plug is especially necessary in periods of darkness and enables to locate the plugs at the moment that a failure is produced. Therefore, the time to restore the service for the critical equipment (loading shovel (111)) becomes considerably shorter.

While the critical equipment is operating normally (loading shovel (111)), each phase (409) of the cable carries currents of the order of hundreds of Amperes. These currents generate a strong perimetral magnetic field to each one of the phases. That magnetic field is concentrated by the ferrous core of the energy harvesting toroid (801). This toroid has an inner diameter of about 40 mm and an outer diameter nearly 60 mm. The height is about 50 mm. These are reference dimensions and they refer to the ferrous core and copper coil.

This outer diameter of the toroid allows to work with the phases of flexible mining cables of 8,000 phase-phase volts and conductor sizes in the range of 1 AWG to 4/0 AWG (American Wire Gauge). The magnetic field concentrated and alternating over time, induces a voltage in the coil (802) terminals which, once rectified (1003), allows to charge the battery (1002).

The epoxy resin disk (506) where are located each of the harvesters has an outside diameter of approximately 150 mm and a thickness of 55 mm. It is important that the outside diameter of the epoxy resin disk be smaller than the inner diameter of the plug in that section (403). Both elements processing the harvested energy (rectifiers, smoothed-wave capacitors (1101)) and the battery itself (1002) can be accessed from outside the plug, so that degraded elements can eventually be replaced. That access from outside is achieved with a casing cover to ensure impermeability inside the plug and its mechanical strength.

The battery (1002) supplies energy directly to LED light (1004) installed on the entire perimeter of the stuffing box, on the outside of the stuffing box and protected by the same structure of the stuffing box. The lights are encapsulated in an epoxy resin so that they are protected against any interaction with the terrain.

The lights require 5 watts-power consumption when they are switched on. This energy is extracted from the battery which can be receiving simultaneously magnetic energy extracted from the conductors of the cable.

### DESCRIBING FIGURES

FIG. 1/11

FIG. 1/11 shows a scheme of the electric distribution network at a mining site as a general case.

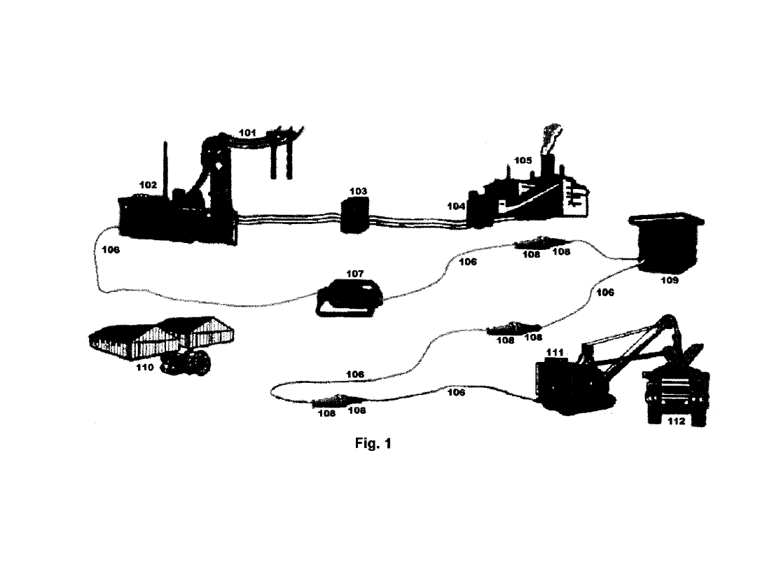

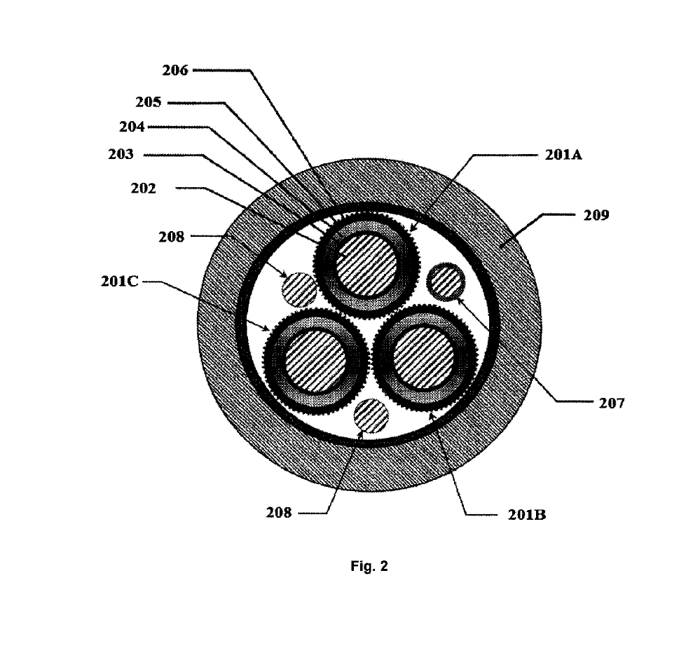

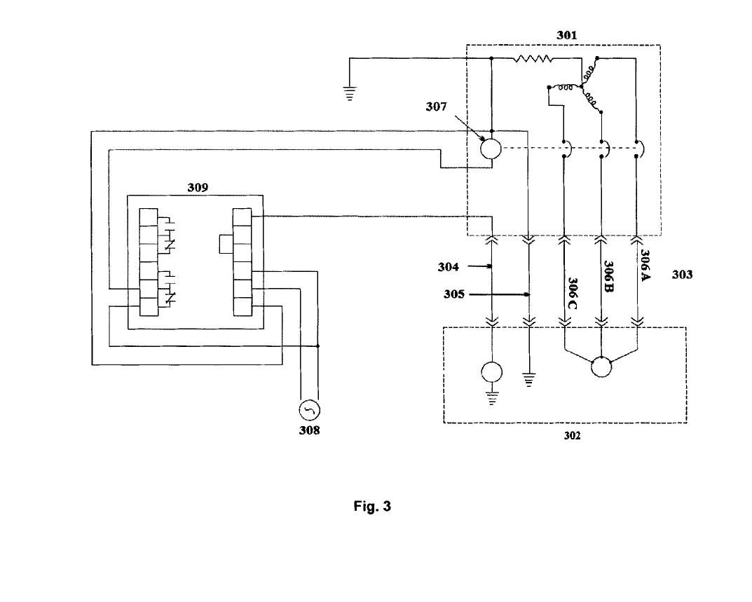

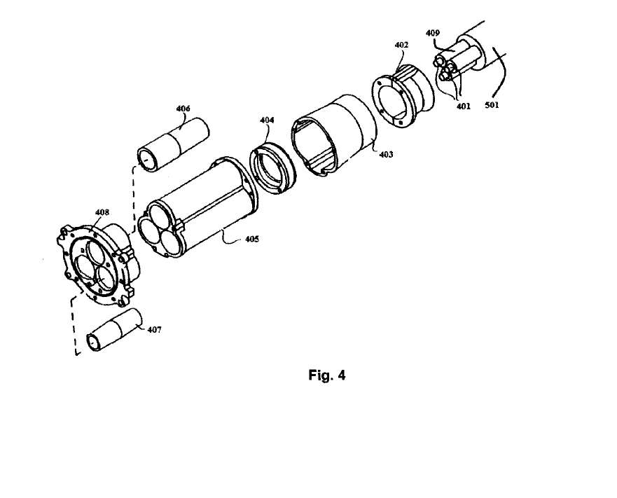

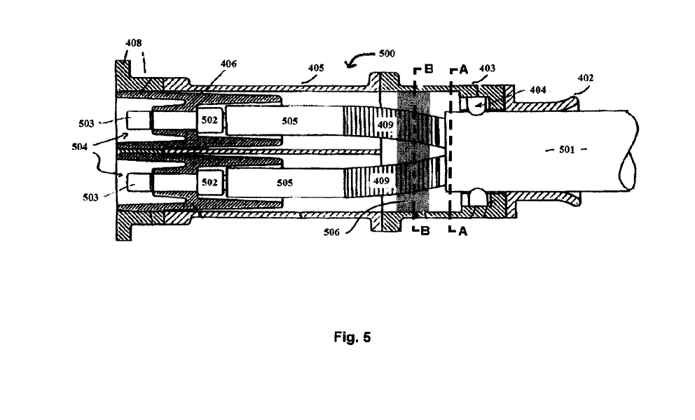

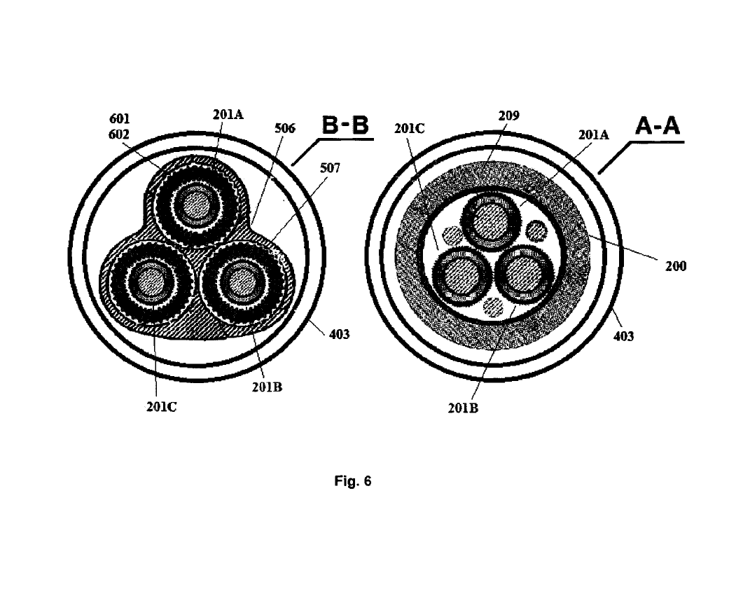

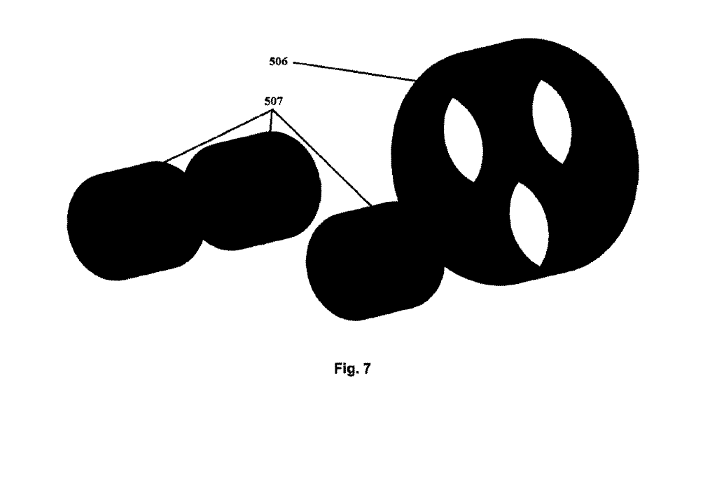

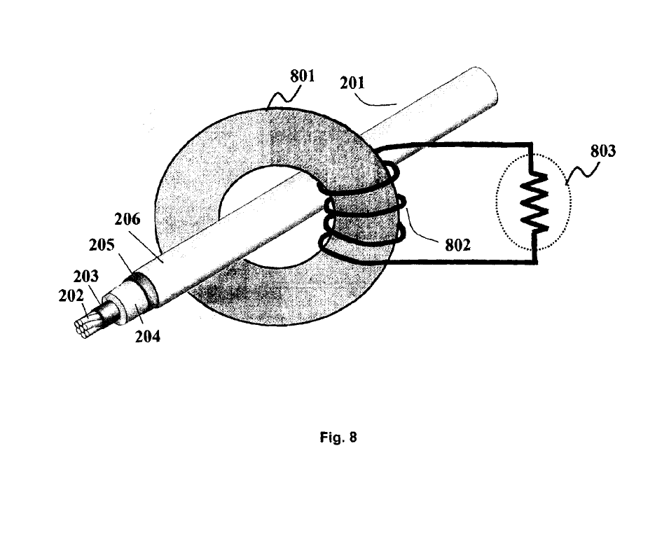

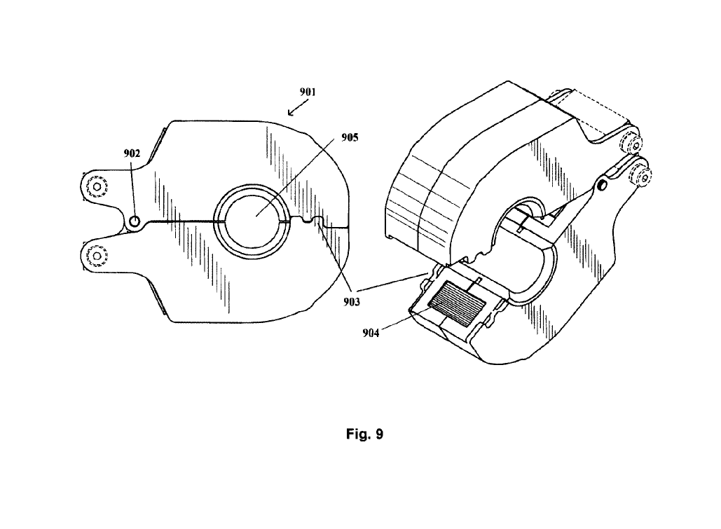

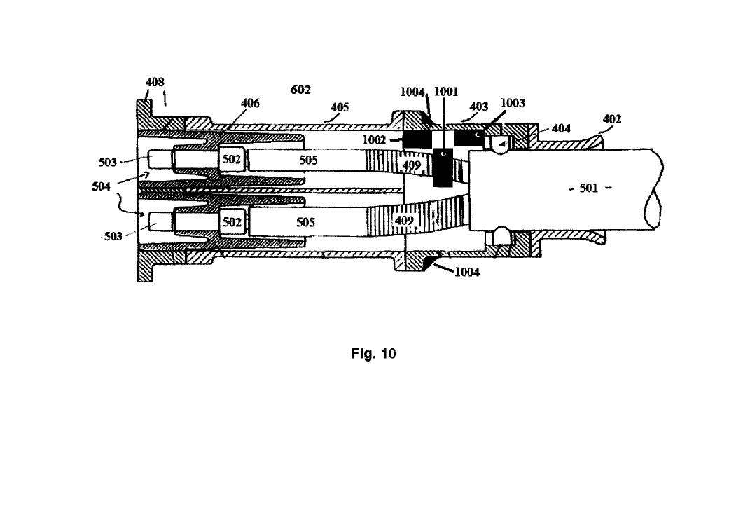

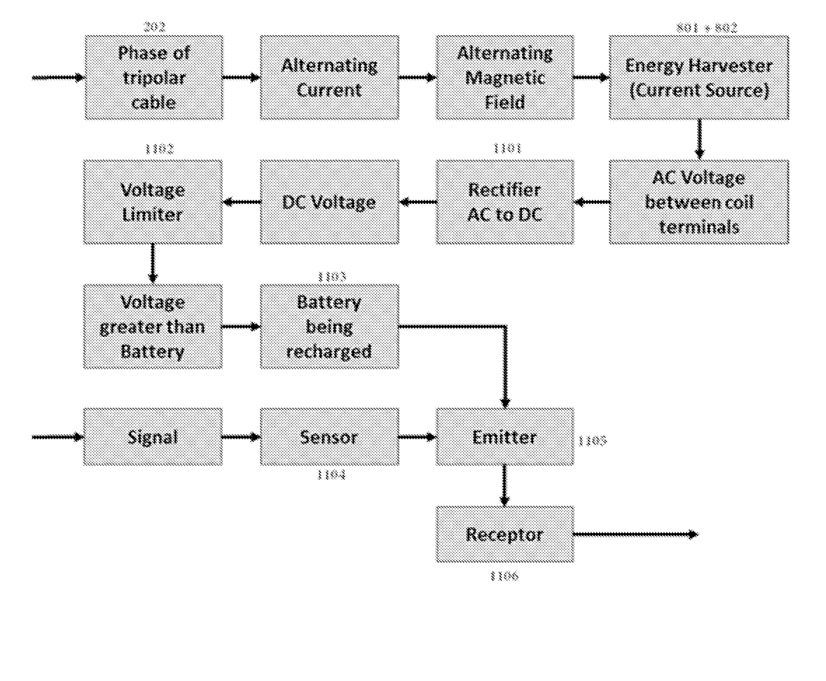

Number 101 shows the high voltage overhead lines supplying electric energy to the mining site.

Number 102 shows a first permanent substation that reduces voltage by lowering high voltage to a distribution voltage, which can be 35.000 volts, 25.000 volts or 15.000 volts.

Number 103 shows an inspection chamber of the underground distribution network of medium voltage.

Number 104 shows a transformer for lowering the voltage for the processing activities such as the casting process or the electro-winning process.

Number 105 shows a building representing the processing activities such as the casting or the electro-winning processes.

Number 106 shows a mining trailing cable of 8,000 volts.

Number 107 shows an industrial plug connecting two sections of trailing cable of 8,000 volts mounted on a sledge.

Number 108 shows an industrial plug that connects two sections of cable of 8,000 volts arranged on the ground just like the cable.

Number 109 shows a mobile substation which allows to power simultaneously one or more equipment.

Number 110 shows schematically a cable workshop where the cables of 8,000 volts damaged during the mine extraction process, are repaired.

Number 111 shows the loading shovel that loads the large-sized trucks. This shovel is electrically powered through the flexible mining cable of 8,000 volts arranged on the ground.

Number 112 shows a mining dump truck which is loaded by the loading shovel with cracked stone after the explosion operation.

FIG. 2/11

FIG. 2/11 is a medium-voltage trailing cable with three phases of power cables.

Number 201A is the complete phase A of the power cable

Number 201B is the complete phase B of the power cable.

Number 201C is the complete phase C of the power cable.

Number 202 is the electric main conductor of power of each phase of the power cable.

Number 203 is a first inner semi-conductive layer of each of the phases of the power cable.

Number 204 is the electrical insulation of each of the phases of the power cables.

Number 205 is the exterior semi-conductive layer of each of the phases of the power cable.

Number 206 is the electrostatic screen of the phases of the power cables.

Number 207 is the pilot wire (207 and 304) of the medium-voltage cable.

Number 208 are the two grounded cables of the medium-voltage cable.

Number 209 is the outer jacket that covers all the above mentioned elements contained in the medium-voltage trailing cable.

FIG. 3/11

FIG. 3/11 is a scheme of the transmission and distribution system.

Number 301 represents the mobile substation (301,109).

Number 302 represents the mobile equipment (302; 111)

Number 303 represents the flexible trailing power cable (303, 106). The cable is schematized as the assembly of the three phases (306A, 306B and 306C), the grounds (305) and the pilot wire (207 and 304)

Number 309 represents the relay that receives the signal from the pilot wire (207 and 304) and the ground (305).

Number 307 is the circuit breaker commanded by the relay (309).

Number 308 is a low-voltage supply source for the relay (302)

FIG. 4/11

FIG. 4/11 is the exploded view of the interior of a mining industrial plug (107, 108, 500)

Number 401 represents each of the three conductors of the flexible three-pole mining cable.

Number 402 is the stuffing box of the flexible three-pole mining cable.

Number 403 is the stuffing box or gland of the flexible three-pole mining cable

Number 404 is the rubber for pressing the flexible three-pole mining cable.

Number 405 is the housing of the insulators.

Number 406 is one of the three insulators. One for each of the phases.

Number 407 is one of the three insulated dual-input female conductors.

Number 408 is the bolted flange connection.

Number 409 is a complete phase of the three phases of the cable: electric power conductor (202 and 401); a first internal semi-conductive layer (203), electrical insulation (204), outer semi-conductive layer (205) and electrostatic screen (206).

FIG. 5/11

FIG. 5/11 represents a longitudinal section of the interior of the assembled plug and two cross-cuttings A-A and B-B.

Number 501 is a flexible three-phase mining cable of 8,000 volts.

Number 502 is the connector head to be bolted or welded to the conductor of each of the three phases of the cable.

Number 503 is the connection pin which guarantees the transmission of electric power with another plug.

Number 504 represents the housing of the insulated female connector.

Number 505 is the phase with its electrical terminal to control the electrical field between phase and earth.

Number 506 is the energy harvester device formed by: (i) a resin that houses the set of three electrical energy harvesters. This device holds together the three harvesting O-rings and keeps them connected with the plug (107, 108, 500) and (ii) the electrical energy harvesting toroid (O-ring) (507)

Number 507 is a harvesting O-Ring formed by a ferrous core, preferably of grain oriented silicon-electrical iron (801) and a coil of electrically conductive material, preferably an enameled annealed copper one (802).

FIG. 6/11

FIG. 6/11 represents two cross-section cuts A-A and B-B of FIG. 5/11.

The cut A-A corresponds to the cross section cut of FIG. 5/11 at the stuffing box level towards the interior of the plug. That is to say, it is the end of the cable that still has its whole structure and elements, as it is the case of the 300 meters conforming it.

The cut B-B corresponds to the cross-section of FIG. 5/11 once the jacket has been extracted and the phases separated. This way, each of the phases (electric power conductor (202), first internal semi-conductive layer (203), electrical insulation (204), outer semi-conductive layer (205) and electrostatic screen (206)) is completely passed through each of the harvesting O-rings (set 801 and 802) as shown in detail in FIG. 8/11

Each of the harvesting O-Rings (set 801 and 802) is embedded in a resin (506) that houses and holds them together in a fixed position with regards to the plug (107, 108,500).

FIG. 7/11

FIG. 7/11 presents an exploded view of the energy harvesting assembly.

Number 506 is the resin that houses the set of three electrical energy harvesters: This piece holds together the three harvesting O-Rings and keeps them connected with the plug (107, 108, 500).

Number 507 is a harvester formed by a ferrous material core, preferably of grain oriented silicon-electrical iron (801) and a coil of an electrically conductive material, preferably an enameled annealed copper one (802). Details are shown in FIG. 8/11.

FIG. 8/11

FIG. 8/11 is the energy harvester (toroid) and one of the phases (main conductor) that passes through it. This harvester should be installed before the plug is completely installed (107, 108, 500) in the cable.

Number 801 is the toroid made of a silicious iron material.

Number 802 is the coil whose material is preferably enameled annealed copper.

Number 803 is an electrical resistance representing a generalization of the diverse loads that may be used to extract energy from the harvester.

FIG. 9/11

FIG. 9/11 represents an open harvester which can be installed once the plug (107, 108, 500) installation has been completed in the cable.

Number 901 represents the harvester itself.

Number 902 is the hinge that allows the harvester to be opened.

Number 903 represents the guides that allow the harvester to be tightly closed, with the consequent closure of the magnetic circuit. This allows the good and efficient operation of the harvester.

Number 904 is the harvester core. This core should be of a ferromagnetic material, generally a silicon iron with grain oriented or not oriented. This iron is shown laminated just as it is usually used to avoid the eddy current induction.

Number 905 is the cavity of the harvester opened to permit the entire phase input with electrostatic screen included.

FIG. 10/11

FIG. 10/11 represents the interior of a plug (107, 18, 500) with the energy harvester system installed.

Number 1001 (501) is the closed core (801) or the open one (901) installed in one of the phases, plus the coil (802)

Number 1002 is the set of: rectifier (1101), voltage limiter (1102), and backup battery (1103)

Number 1003 is the set of: sensor (1104) and emitter (1105).

Number 1004 is a ring of LED lights indicating the presence of the industrial plug (107, 108, 500). The ring is protected by the external design of the plug and a transparent cover made of a highly-hard epoxy polymer material.

FIG. 11/11

FIG. 11/11 is a general scheme of the system: three pole phase (202), harvester (801+802), rectifier (1101), voltage limiter (1102), battery (1103), sensor (1104), emitter (1105).

Number 1101 is the system rectifier that transforms alternating current into continuous current. It is a typical arrangement of four diodes forming a Weston bridge and a capacitor for smoothing the wave shape to obtain a continuous current.

Number 1102 is the system voltage limiter that intends to limit the voltage applied to the battery in order to extend its service life.

Number 1103 is the battery of the system. It works as a backup of energy when there is no current in the three-pole power cable that powers the mobile equipment (loading shovel and/or drilling machine).

Number 1104 is the system signal sensor which captures a determined signal that may be temperature, current, humidity, geographic position of satellite coordinates, phase voltage, etc. This sensor is powered by the battery so that it may be working as long as the battery has enough charge to make it work.

Number 1105 is the system's signal emitter. This emitter emits a certain signal to provide a receiver (1106) useful information. The emitter informs about: (i) state of the plug (107, 108, 500), presence of voltage in the plug (107, 108, 500), presence of the plug (107, 108, 500) by means of luminous signals, telecommunication signals such as radiofrequency, GPS, etc.; (ii) state of the distribution line, or the magnitude of a determined parameter. This emitter is powered by the battery so that it may be operating as long as the battery has the enough charge to make it work.

Number 1106 is the signal receiver. This receiver can be a determined element or a person to whom the emitted signal is useful.

1. Industrial plug with an energy harvesting capabilities CHARACTERIZED because it contains one or three phases of a power cable, an electromagnetic energy harvesting device that is positioned around to one or each of the phase of the power cable and an industrial plug housing the whole device.

2. Industrial plug described in the claim 1, CHARACTERIZED because the power cable is preferably a three-phase one.

3. Industrial plug described in the claim 1, CHARACTERIZED because the power cable is preferably a single-phase one.

4. Industrial plug described in the claim 1, CHARACTERIZED because the power cable is insulated.

5. Industrial plug described in the claim 1, CHARACTERIZED because the power cable is a low, medium or high voltage cable.

6. Industrial plug described in the claim 5, CHARACTERIZED because the power cable is a medium voltage one.

7. Industrial plug described in the claim 1, CHARACTERIZED because the electromagnetic energy harvesting device comprises a ferrous core wounded by coils to which loads and optionally backup batteries or both are connected.

8. Industrial plug described in the claim 7, CHARACERIZED because the loads are energized through the energy harvesting device, without making direct electrical contact with the power cable.

9. Industrial plug described in the claim 7, CHARACTERIZED because the ferrous core is made of a ferromagnetic material, preferably silicon iron of oriented grain.

10. Industrial plug described in the claim 9, CHARACTERIZED because the ferrous core is configured as a closed hard core when operating.

11. Industrial plug described in the claim 9, CHARACTERIZED because the ferrous core when it is installed is configured as an open core that will close whenever in operation.

12. Industrial plug described in the claim 7, CHARACTERIZED because the coil is made of an electric conductive material, electrically insulated, preferably enameled annealed copper.

13. Industrial plug described in the claim 7, CHARACTERIZED because the loads consume the energy provided by the coil.

14. Industrial plug described in the claim 7, CHARACTERIZED because the loads consuming the energy provided by the coil comprises different elements such as LED lights, satellite positioning systems, voltage detectors, sound generators and working parameters of the industrial plug.

15. Industrial plug described in the claim 14, CHARACTERIZED because the loads that consume the energy provided through the coil are LED lights.

16. Industrial plug described in the claim 7, CHARACTERIZED because the batteries store the energy provided by the coils and are able to deliver it to the loads when there is no current in the conductor.

17. Industrial plug described in the claim 7, CHARACTERIZED because the elements which store the energy provided by the coil comprise capacitors, super capacitors and/or batteries.

18. Industrial plug described in the claim 7, CHARACTERIZED because the batteries store the energy provided by the coil and are able to deliver it with a power of units, dozens and even hundreds of watts.

19. Industrial plug described in the claim 1, CHARACTERIZED because optionally depending on the type of current required, comprises the following elements: (i) rectifier/regulator of voltage (1101) and (ii) information process card, all incorporated inside the plug (107, 108, 500)

20. Industrial plug described in the claim 1, CHARACTERIZED because the plug comprises: a center, hollowed, grounded housing reinforced with ribs inside which provide the mechanical strength to withstand the mining operation, made of metallic material and/or polymeric material; with capacity to control the electric field through the insulators inside. In both ends of the plug: (i) in one end the three-pole cable (501) is fixed to the plug by tightening of the outer jacket (209) of the cable (501) with the stuffing box (402); (ii) the other end of the plug is the connection face to join another plug; in this end there are three independent phases (out of the jacket) connected electrically with the phases of the other cable through the connection pins (503); the plug is internally arranged in a manner that a space is generated to incorporate the energy extractor device (506) inside the central housing of the plug or inside the collar of the stuffing box (403), that is to say, the electric energy harvester device (506) is located inside the plug, in the section closer to the plug tail end wherein the phases already are out of the cable jacket and separated from one another.

21. Industrial plug described in the claim 20, CHARACTERIZED because the configuration and arrangement are the same for male and female plugs and for those plugs do not require the gender characteristic (male, female) to operate.

22. Industrial plug described in the claim 1, CHARACTERIZED because it has a minimum generation capacity of 5 watts of power.

23. Industrial plug described in the claim 1, CHARACTERIZED because it increases at most 10%, the weight and dimensions of the plug, besides it does not modify the conventional installation and connection of the industrial plug.

24. Use of the industrial plug described in the claim 1, CHARACTERIZED because it is used for detecting voltage presence inside the industrial plug and specifically of that particular industrial plug.

25. Use of the industrial plug described in the claim 1, CHARACTERIZED because it is used in the satellital positioning of the industrial plug.

26. Use of the industrial plug described in the claim 1, CHARACTERIZED because it is used in the illumination and identification of the industrial plug.

27. Use of the industrial plug described in the claim 1, CHARACTERIZED because it is used in the monitoring of plug working parameters.

28. Use of the industrial plug described in the claim 27, CHARACTERIZED because it is used in the monitoring of operation parameters, electrical parameters, physical variables in transmission networks and substations, ambient variables among others.

29. Use of the industrial plug described in the claim 1, CHARACTERIZED because it is used in the emission of sounds.

30. Use of the industrial plug described in the claim 1, CHARACTERIZED because it is used as energy storage.

31. Use of the industrial plug described in in the claim 1, CHARACTERIZED because it is use as a captor of electromagnetic field.

32. Use of the industrial plug described in the claim 1, CHARACTERIZED because it uses the electromagnetic energy generated by the current circulating inside the power cable.
